(19) United States
(12) Patent Application Publication
(10) Pub. No.: US 2026/0285775 A1
(43) Pub. Date: Sep. 24, 2026

(54) Mit Diamant beschichtetes AlN-Substrat und Verfahren zum Herstellen

(71) Applicant: CONDIAS GmbH, Itzehoe (DE)

(72) Inventors: Benjamin Cymann, Itzehoe (DE); Tobias Graßl, Hohenaspe (DE); Dirk Mathiak, Itzehoe (DE); Thorsten Matthée, Hohenaspe (DE); Rieke Neuber, Halstenbek (DE)

(21) Appl. No.: 19/360,263

(22) Filed: Oct. 16, 2025

(30) Foreign Application Priority Data
Oct. 21, 2024 (DE) 10 2024 130 537.1

(51) Int. Cl. C04B 41/52; C04B 35/581; C04B 41/45; C04B 41/50

(52) U.S. Cl. CPC C04B 41/524; C04B 35/581; C04B 41/4531; C04B 41/5001

(57) ABSTRACT

An aluminum nitride substrate which is or forms part of a device, is coated on an upper side with a diamond layer. On a lower side of the substrate includes a coated area with a carbon-based coating containing at least 50% sp2 configured carbon. Also on the lower side is a free area which has a thinner carbon-based coating than is positioned in the coated area. The free area covers at most 10% of the lower side of the substrate and may be formed from a plurality of partial areas. Either or both the upper side or lower side of the substrate may include a structural element such as an elevation or a depression.

The invention relates to a device with a substrate made of aluminum nitride (AIN) that comprises an upper side and a lower side opposite the upper side, wherein the surface is coated with a diamond layer. The invention also relates to a method for coating a surface of a substrate made of aluminum nitride with a diamond layer in a CVD reactor.

From the prior art, it is known to apply a diamond layer to a substrate in order to be able to utilize the often advantageous properties of the diamond. For example, electrodes for electrochemical cells are coated with a doped diamond layer in order to exploit the fact that the diamond layer is chemically inert and both mechanically and thermally very stable, wherein the doping is necessary in order to increase the conductivity of the otherwise electrically insulating diamond layer. In other applications, the mechanical hardness and resistance of diamond are exploited.

A CVD reactor is often used to apply a diamond layer to a substrate, such as single-crystal silicon. CVD stands for “chemical vapor deposition”. The CVD method has been known from the prior art for many years. The carbon required to form the diamond layer is obtained from methane introduced into the reactor. The challenge is in selecting the process parameters in such a way that a diamond layer is actually deposited and not any other possible carbon layer. If a single crystal is used as a substrate, for example one made of silicon, the adhesion of the deposited diamond layer is usually strong enough to use the coated substrate for the respective application. A substrate coated on both sides with a diamond layer, which is intended as an electrode for electrochemical applications, is known from DE 10 2021 110 857 A1. The type and quality of the deposited diamond layer depends on a number of parameters, which have to be adjusted as precisely as possible. This is highlighted, for example, in DE 696 29 980 T with regards to temperature.

The prior art has attempted to also coat aluminum nitride substrate, i.e. a substrate made from a ceramic, with a diamond layer, using the CVD method to do so. This can be seen, for example, in DE 197 10 202 A1 and CN 1 13 755 819. However, this leads to poorer adhesion of the deposited diamond layer on the substrate than is expected and needed. In the context of the present invention, an aluminum nitride substrate is an aluminum nitride ceramic that may additionally contain aggregates used during the production of the ceramic to influence chemical, thermal and/or mechanic properties of the ceramic, which is often subjected to a sintering process. There are therefore various reasons why coating an aluminum nitride ceramic is difficult. One possible problem is aluminum residues, i.e. more or less large areas of metallic aluminium which may melt at the high temperatures that occur during CVD coating. Aluminum has a melting temperature of approximately 660° C. Temperatures in a CVD reactor can reach up to 900° C., meaning that metallic aluminum melts. At the points where there is metallic aluminum on the surface, the substrate liquefies so that a diamond layer can no longer be applied to it. Due to the high vapor pressure of the aluminum, a significant proportion of the aluminum may also pass into the gaseous state and contaminate both the coating deposited from the gas atmosphere that prevails in the CVD reactor and the reactor itself such that it can only be used again following a complex, time-consuming and expensive thorough cleaning.

The aggregates, such as Y₂O₃, added to the ceramic are often unknown, which can pose another problem. Since their composition and their melting points, boiling points or gas pressure are often unknown, it is almost impossible to predict how the aggregates behave when coating the surface of the substrate and whether they will withstand or be suitable for coating at all.

A further difficulty is the fact that the aluminum nitride of the substrate and the diamond layer to be applied have very different crystallographic properties. The aluminum nitride is a polycrystalline ceramic, wherein the aluminum nitride crystal comprises an hcp lattice. The abbreviation hcp stands for “hexagonal close-packed”. The diamond layer, however, grows in a cubic crystal lattice, wherein the (1 1 1) plane of this cubic lattice exhibits a large mismatch with the hop lattice.

The invention aims to improve a device according to the preamble of claim 1 and to propose a method with which a surface of an aluminum nitride substrate can be coated with a diamond layer in a CVD reactor.

The invention solves the task addressed by way of a device with a substrate made of aluminum nitride with an upper side and a lower side opposite the upper side, the upper side being coated with a diamond layer, wherein the device is characterized in that a coated area of the lower side has a carbon-based coating containing at least 50% sp2 configured carbon and a free area of the lower side has a thinner carbon-based coating than the coated area, wherein, irrespective of the thickness profile of the carbon-based coating in the coated area of the lower side, the thickness of the coating in the free area is lower than in the part of the coated area that immediately surrounds or abuts said free area, the free area constituting at most 10% of the lower side of the substrate.

The carbon-based coating, which is found on the lower side of the substrate, has a thickness that does not have to be constant. Preferably, the thickness of the coating in the coated area decreases as the distance from the edge of the lower side of the substrate increases. The thickness of the coating may also be constant in the coated area. A carbon-based coating may also be provided in the free area of the lower side of the substrate. The term “free area” is therefore not to be understood to mean that this area has to be free from any coating. However, the thickness of the coating provided in this free area is lower than the carbon-based coating in the coated area of the lower side of the substrate. Irrespective of the thickness profile of the carbon-based coating in the coated area of the lower side, the thickness of the in situ deposited coating in the free area of the lower side is lower than in the part of the coated area that immediately surrounds or abuts said free area. This does not necessarily mean that the thickness if the carbon-based coating is greater at every point of the coated are than the thickness at every point of the free area, even is this is a preferred embodiment. It is indeed possible that the thickness of the coating in one free area is greater than the thickness at one point of the coated area. For example, this is possible if the free area lies at the edge of the lower side of the substrate and the point of the coated area is far away from the edge of the lower side.

Preferably, the carbon-based coating has a step at the boundary between the coated area and the free area. Here, a step refers in particular to an area where the derivative of the thickness according to location assumes a significantly greater value than at other points on the lower side.

The free area preferably does not have a carbon-based coating, meaning that the thickness of the coating in this area is zero.

The carbon-based coating on the lower side preferably also extends on the lateral surface of the substrate that connects the upper side to the lower side. The thickness of the carbon-based coating on the lateral surface of the substrate preferably decreases, starting from the upper side, towards the lower side of the substrate.

The carbon-based coating on the lower side of the substrate and, where applicable, also on the lateral surface of the substrate is applied to the upper side of the substrate in the same coating step as the diamond layer. To apply the carbon-based coating to the lower side of the substrate, the lower side cannot lie fully on a sample table; rather, it has to come into contact with the gas atmosphere inside the coating reactor, for example a CVD reactor. To achieve this, it is advantageous to rest the substrate on one or multiple supports so that there is a gap between the lower side of the substrate and the sample table into which the gas atmosphere can enter. The lower side of the substrate is usually at a temperature that is often not sufficient to deposit a diamond layer, but is high enough for another carbon-based material to form.

At the points where the lower side of the substrate rests on the at least one support, the gas atmosphere does not come into contact with the lower side of the substrate or only does so to a small extent so that at these points there is at least a part of the free area where there is only a thinner or even no carbon-based coating on the lower side of the substrate.

The invention is based on the knowledge that the adhesion of the diamond coating on the upper side of the substrate is improved if the carbon-based coating is on the lower side of the substrate in a coated area and there is at least one free area in which only a thinner or even no such coating is provided.

The free area preferably extends annularly, particularly preferably in the shape of a circular ring or polygonally. Preferably, the free area is made up of a plurality of separate partial areas. Each of these partial areas may be designed to be circular, oval or polygonal, or may have another free form. The various partial areas can be the same shape and/or the same size. The various partial areas can be different shapes and/or different sizes. In one preferred embodiment, some of the partial areas extend in a partial ring shape and together form an open annular free area, preferably an open circular or polygonal free area.

In preferred embodiments, the free area constitutes at most 6%, particularly preferably at most 3%, of the lower side of the substrate.

Preferably, the upper side of the substrate comprises at least one structural element, in particular at least one elevation and/or at least one depression. The lower side of the substrate preferably has at least one structural element, in particular an elevation and/or at least one depression. Such an elevation or depression preferably has a height or depth of at least 1 mm, preferably at least 2 mm, and at most 10 mm, preferably at most 8 mm.

Advantageously, at least one structural element of the lower side lies in the area of the lower side that only has a thinner carbon-based coating or even none at all. Advantageously, all structural elements of the lower side lie in the area of the lower side that only has a thinner carbon-based coating or even none at all.

Preferably, at least one structural element provided on the lower side or the upper side of the substrate is a depression into which an electronic component, such as a sensor, can be inserted in a subsequent step in the process. Alternatively or additionally, at least one structural element is a trench or a groove into which electrical cables or signal cables are to be laid in a subsequent step in the process. As a result, it is advantageous if these structural elements are not covered by a carbon-based coating.

Preferably, the diamond coating on the upper side of the substrate contains less than 5%, preferably less than 3%, especially preferably less than 1% sp2 configured carbon.

Part of the carbon-based coating is sp2 configured carbon. Preferably, the carbon-based coating on the lower side of the substrate contains at least 70%, especially preferably at least 90%, sp2 configured carbon. The carbon-based coating may be in part a diamond coating and/or a diamond-like coating (DLC). Preferably, the 100% missing portion of the carbon-based coating is a diamond coating and/or a diamond-like coating.

The device between the aluminum nitride of the substrate and the diamond layer on the upper side of the substrate preferably comprises carbon alumium nitride (molecular formula AlCN).

Preferably, the diamond layer on the upper side of the substrate is doped, the doping preferably containing boron and/or phosphorus and/or nitrogen.

In one preferred embodiment, the diamond layer has a homogeneous thickness. This is the case, for example, when the diamond layer at the thickest point of the diamond layer is a maximum of 2 μm, preferably a maximum of 1 μm, particularly preferably a maximum of 0.2 um thicker than at the thinnest point of the diamond layer.

In preferred embodiments, the lower side of the substrate also has a diamond coating on which and/or under which the carbon-based coating is arranged. This embodiment can be produced, for example, by depositing the diamond layer on the upper side of the substrate in a first coating step and simultaneously depositing the carbon-based coating on the lower side of the substrate. The substrate is then turned over so that the diamond-coated upper side is underneath. A second coating step is carried out in this position during which the lower side is now given a diamond layer. When coating the lower side with diamond, the layer thickness of the previously deposited carbon-based coating on the lower side is reduced by way of the diamond coating.

As an alternative, the lower side of the substrate can also be coated with a diamond later in a first coating step. To this end, the substrate is introduced into the reactor with the lower side facing upwards. Once the diamond layer has been applied to the lower side of the substrate, the substrate is rotated and coated again with the upper side facing upwards. In this second coating step, the diamond layer is created on the upper side of the substrate and the carbon-based coating is simultaneously created on the lower side of the substrate. Said carbon-based coating is therefore deposited on the diamond layer and is thus located on the diamond layer.

The invention also solves the task addressed by way of a method for coating a surface of a substrate made of aluminum nitride with a diamond layer in a CVD reactor comprising the following steps:
a. corroding the surface outside of the reactor using a corrosion agent, resulting in a prepared surface,
b. seeding the prepared surface with diamond particles,
c. positioning the substrate with the seeded surface on a sample table, wherein the substrate rests on at least one support,
d. positioning the sample table with the substrate in the reactor,
e. heating the reactor and the substrate to an operating temperature and
f. depositing the diamond layer on the surface and a carbon-based coating containing at least 50% sp2 configured carbon on a lower side of the substrate.

In a first step, the surface to be coated with the diamond layer is corroded outside of the reactor. For example, chemical corrosion agents are used to remove contaminants from the surface. Preferably, at least 90%, preferably at least 95%, especially preferably 100% of the contaminants present on the surface, especially organic and/or metallic contaminations of the surface, are removed. The surface treated in this manner is prepared for seeding and is therefore referred to as a prepared surface.

The prepared surface is seeded with diamond particles. In principle, seeding the surface of a substrate is known from the prior art. For example, a suspension is prepared that contains micro-crystalline and/or nano-crystalline diamond particles. They are applied to the surface to be coated with the diamond layer.

The substrate is positioned on a sample table following seeding. The sample table is then positioned with the substrate positioned on it in the reactor. The exact positioning is very important. In order to minimize any problems that may arise from the presence of metallic aluminium or other aggregates, it is advantageous for the diamond layer to grow and be deposited on the surface to be coated as quickly as possible. For this purpose, it is advantageous if the largest possible area of the surface, particularly preferably the entire surface, is at a temperature that is sufficient for coating and depositing the diamond layer, which is achieved by filaments in the CVD reactor that are heated by an electrical current. Here, it is extremely important to align the substrate in relation to the filaments in such a way that as much of the generated heat as possible can be captured by the largest possible area of the surface.

The reactor and the substrate arranged therein are then heated to an operating temperature, which can be 900° C., for example. The diamond layer is then deposited onto the surface of the substrate.

Preferably, a diamond layer is deposited on the lower surface of the substrate in a further step in the process, wherein the substrate is preferably rotated beforehand.

In one preferred embodiment, the corrosion agent is or contains phosphoric acid (H₃PO₄). This is a cheaper and considerably more preferable choice of corrosion agent in terms of occupational safety than hydrogen fluoride (HF), which is referred to as hydrofluoric acid and is likewise known as a corrosion agent from the prior art.

Preferably, seeding occurs before the substrate is positioned in the reactor.

The substrate is preferably positioned on the sample table resting on multiple supports. The substrate therefore does not lie fully on the sample table, as is known from the prior art, but rests on the supports that ensure that an area of the lower side of the substrate comes into the gas atmosphere inside the reactor. The carbon-based coating is applied to this area of the lower side, while the upper side is coated with the diamond layer.

This significantly reduces the thermal contact to other objects, especially the sample table, which means that less heat can be diverted from the substrate into the other objects, especially the sample table. As a result, the surface of the aluminum nitride substrate facing the supports reaches the temperature required for depositing the diamond layer more quickly, for longer, more homogeneously and preferably in a larger area as well. On the one hand, this means that larger substrates and larger surfaces can be coated and, on the other hand, that the diamond layer can be deposited more quickly, thus forming a closed coat over the surface of aluminum nitride substrate so that issues caused by metallic aluminum and/or unknown aggregates of the aluminum nitride ceramic can be eliminated as quickly as possible. Once the diamond layer has formed a closed coat on the surface of the substrate, this diamond layer is further coated and grows as the coating process continues. Any foreign substances, aggregates or metallic phases found underneath can no longer and/or influence the coating.

There are preferably at least three supports on which the substrate rests. The positions of the three or more supports preferably form an equilateral triangle or a polygon which, on the one hand, is designed to be so big that the substrate rests securely on the supports and, on the other hand, is designed to be as small as possible in order to position the contact area between the supports and the back of the substrate as closely as possible to the middle of the substrate. The supports can also be designed such that they are positioned at the edge of the lower side. They are preferably in contact with the edges of the substrate where the lower side of the substrate abuts a lateral surface of the substrate. The supports can also be designed such that they are arranged on at least one lateral surface of the substrate and are preferably firmly attached to the substrate during coating. The free area of the lower side is then formed by the coating shadow of the supports.

Preferably, extensions are arranged on the substrate that protrude beyond the edge of the lower side of the substrate. In this case, it is advantageous to arrange at least some of the supports, but preferably all the supports, on these extensions.

The central area of the surface of the substrate is heated most strongly by the filaments such that heat is most likely to flow off here without the temperature dropping below the temperature required to deposit the diamond layer. Preferably, more than 3, for example at least 6, preferably at least 10, particularly preferably at least 20 supports are provided on which the substrate rests. The greater the number of supports, the more evenly they can be distributed such that the distances between two supports can be reduced, which reduces a deflection of the substrate and likewise reduces the mechanical tensions that may be caused by resting on few points.

Preferably, an enclosure element is positioned on the sample table that at least partially, but preferably completely, encloses the substrate in a plane parallel to the sample table. It is thus possible to counteract the effect that the edge area of the substrate is coated to a disproportionately large extent when no enclosure element is provided. The enclosure element has an upper side that preferably ends flush with the edge of the surface of the substrate. The edge of the surface is preferably the edge where the surface of the substrate and the lateral surface of the substrate meet. There may be a gap between the edge of the surface of the substrate and the enclosure element that is preferably a circumferential gap, wherein said gap is preferably as small as possible so as to increase the effect of the enclosure element of the diamond layer to be deposited. Said gap preferably has a width of at most 2 mm, preferably at most 1 mm. The surface of the substrate to be coated with the diamond layer is advantageously designed to be flat, i.e. it forms a section of a flat surface. In this case, the upper side of the enclosure element preferably also extends in this plane.

In preferred embodiments of the method, an atmosphere in the reactor when heating the reactor preferably contains so little methane that the atmosphere of the prepared surface corrodes. On the one hand, this means that in this step in the process, no carbon and therefore no diamond is deposited yet on the surface to be coated. On the other hand, due to the corrosive effect of the atomic hydrogen of the atmosphere, a contamination of the surface, for example due to the reaction with substances and materials in the atmosphere, is prevented.

Preferably, the surface of the substrate has an expansion in at least one direction of at least 15 cm, preferably at least 20 cm, particularly preferably at least 25 cm.

Preferably, the substrate does not extend more than 1 m in this direction.

In the following, an embodiment example of the invention will be explained in more detail with the aid of the accompanying figures. They show:

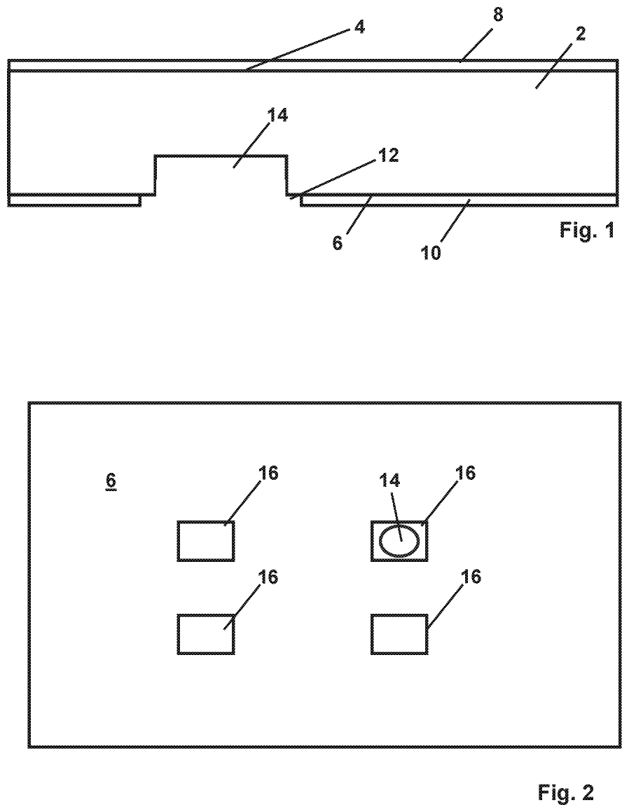

FIG. 1—a schematic sectional view through a device according to an embodiment example of the present invention and

FIG. 2—a schematic representation of the lower side of a device according to a further embodiment example of the present invention.

FIG. 1 depicts a schematic sectional view through a device according to an embodiment example of the present invention. It has a substrate 2 made of aluminum nitride, which has an upper side 4 and a lower side 6. There is a diamond layer 8 on the upper side 4 which, in the embodiment example shown, completely covers the upper side 4 of the substrate 2. This is advantageous for all embodiments described. There is a carbon-based coating 10 on the lower side 6. However, it does not cover the entire lower side 6, but only the coated area of the lower side. There is a gap in the carbon-based coating which forms the free area 12 of the lower side 6. The lower side 6 of the substrate 2 comprises a structural element 14 in the form of a depression. Said structural element 14 is located in the free area 12 of the lower side 6 and is therefore not covered by the carbon-based coating 10. This is advantageous, but not essential. It is also possible that a structural element is arranged in the coated area of the lower side 6 and then correspondingly covered with the carbon-based coating.

FIG. 2 shows a schematic representation of a lower side 6 of a device according to a further embodiment example of the present invention. The lower side has four partial areas 16, each of which is rectangular. Of course, other geometric shapes are possible. Together, the partial areas 16 form the free area 12 of the lower side 6. In the partial area 16 shown at the top right of FIG. 2 a structural element 14 is also schematically depicted, said element being in the form of a depression.

### REFERENCE LIST

2 substrate
4 upper side
6 lower side
8 diamond layer
10 carbon-based coating
12 free area
14 structural element
16 partial area

1. A device, comprising: with
a substrate made of aluminum nitride, wherein said substrate comprises an upper side and a lower side, wherein the lower side is (6) opposite the upper side;
a diamond layer coated on the upper side of the substrate;
a coated area coated on the lower side comprising a carbon-based coating containing at least 50% sp2 configured carbon; and
a free area as part of the lower side, wherein the free area comprises a thinner carbon-based coating that is thinner than the carbon-based coating on the coated area of the lower side,
wherein, irrespective of a thickness profile of the carbon-based coating in the coated area of the lower side, a thickness of the thinner carbon-based coating in the free area is less than in a part of the coated area that immediately surrounds or abuts the free area
wherein the free area constitutes at most 10% of the lower side of the substrate

2. The device according to claim 1 wherein the free area extends annularly on the lower side of the substrate.

3. The device according to claim 1, wherein the free area on the lower side of the substrate is comprised of a plurality of separate partial areas.

4. The device according to claim 1, wherein one of the free area forms at most 6% of the lower side, the of the substrate.

5. The device according to claim 1, wherein the upper side of the substrate comprises at least one structural element.

6. The device according to claim 1, wherein the lower side of the substrate comprises at least one structural element.

7. The device according to claim 6, wherein the at least one structural element lies in the free area of the lower side.

8. The device according to claim 1, wherein the diamond layer coated on the upper side of the substrate contains less than 5% sp2 configured carbon.

9. The device according to claim 1, wherein the carbon-based coating on the lower side of the substrate contains at least 70% sp2 configured carbon.

10. The device according to claim 1, wherein the diamond layer is doped, with boron and/or phosphorus and/or nitrogen.

11. The device according to claim 1, wherein a one of thickest point of the diamond layer is a maximum of 2 μm; thicker than at a thinnest point of the diamond layer.

12. The device according to claim 1, wherein the lower side of the substrate comprises a lower side diamond coating on which and/or under which the carbon-based coating of the coated area is arranged.

13. A method for coating substrate made of aluminum nitride, comprising
a. corroding an upper side of the substrate outside of a reactor using a corrosion agent, resulting in a prepared upper side,
b. seeding the prepared upper side with diamond particles to form a seeded upper side,
c. positioning the substrate with the seeded upper side on a sample table, wherein the substrate rests on at least one support,
d. positioning the sample table with the substrate with the seeded upper side in the reactor,
e. heating the reactor and the substrate to an operating temperature, and
f. depositing a the diamond layer on the upper side of the substrate and a carbon-based coating containing at least 50% sp2 configured carbon on a lower side of the substrate.

14. The method according to claim 13, further comprising depositing a lower side diamond layer on a the lower surface of the substrate.

15. The device according to claim 5, wherein the at least one structural element is selected from the group consisting of an elevation and a depression.

16. The device according to claim 6, wherein the at least one structural element is selected from the group consisting of an elevation and a depression.

17. The method according to claim 14 further comprising rotating the substrate prior to depositing the lower side diamond layer.
